(19) United States
(12) Patent Application Publication
(10) Pub. No.: US 2012/0127640 A1
(43) Pub. Date: May 24, 2012

(54) ELECTRONIC APPARATUS

(75) Inventor: Yuji Nakajima, Nishitama-gun (JP)

(73) Assignee: KABUSHIKI KAISHA TOSHIBA, Tokyo (JP)

(21) Appl. No.: 13/214,994

(22) Filed: Aug. 22, 2011

(30) Foreign Application Priority Data
Nov. 19, 2010 (JP) 2010-259168

(51) Int. Cl. H05K 7/00

(52) U.S. Cl. 361/679.01

(57) ABSTRACT

According to one embodiment, an electronic apparatus includes a display panel, a first member, a second member, a pair of elastic bodies and a heating element. The first member includes a thermally expandable first main body surrounding a first face of the display panel, and a pair of first projections projecting from the first main body. The second member includes a second main body surrounding a second face of the display panel, and a pair of second projections projecting from the second main body to be located on inner sides of the first projections. Each of the elastic bodies is provided between a first projection and a second projection, and force the first main body outward before the first main body has thermally expanded and after the first main body has thermally expanded.

### CROSS-REFERENCE TO RELATED APPLICATIONS

This application is based upon and claims the benefit of priority from Japanese Patent Application No. 2010-259168, filed Nov. 19, 2010; the entire contents of which are incorporated herein by reference.

### FIELD

Embodiments described herein relate generally to an electronic apparatus comprising a display panel.

### BACKGROUND

In some types of electronic apparatuses, such as cellular phones, thermal expansion is suppressed to deal with a change in temperature of a surrounding environment.

There has been a demand for a countermeasure against thermal expansion resulting from a heated part inside the casing of an electronic apparatus, not only the change in temperature of the surrounding environment.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary front view showing a television as an example of an electronic apparatus according to a first embodiment;

FIG. 2 is an exemplary sectional view taken along a line F2-F2 shown in FIG. 1;

FIG. 3 is a sectional view taken along a line F3-F3 shown in FIG. 1;

FIG. 4 is an exemplary exploded sectional view showing a part of a television as an example of an electronic apparatus according to a second embodiment;

FIG. 5 is an exemplary enlarged sectional view showing a first projection and a surrounding portion in a television as an example of an electronic apparatus according to a third embodiment;

FIG. 6 is an exemplary enlarged sectional view showing a first projection and a surrounding portion in a television as an example of an electronic apparatus according to a fourth embodiment;

FIG. 7 is an exemplary enlarged sectional view showing a second projection and a surrounding portion of a television as an example of an electronic apparatus according to a fifth embodiment;

FIG. 8 is an exemplary perspective view showing a portable computer as an example of an electronic apparatus according to a sixth embodiment;

FIG. 9 is an exemplary exploded perspective view showing a display of the portable computer shown in FIG. 8;

FIG. 10 is an exemplary perspective view schematically showing a second member and a display panel of the portable computer shown in FIG. 8;

FIG. 11 is an exemplary perspective view showing a first member of the portable computer shown in FIG. 9;

FIG. 12 is an exemplary enlarged perspective view showing a second projection on a right side of the second member shown in FIG. 9 and a surrounding portion;

FIG. 13 is an exemplary enlarged perspective view showing a second projection on a left side of the second member shown in FIG. 9 and a surrounding portion;

FIG. 14 is an exemplary sectional view taken along a line F14-F14 shown in FIG. 13;

FIG. 15 is an exemplary exploded sectional view showing the portable computer shown in FIG. 8;

FIG. 16 is an exemplary sectional view showing a first state in which a first main body of the portable computer shown in FIG. 8 has not expanded;

FIG. 17 is an exemplary sectional view showing a second state in which the first main body of the portable computer shown in FIG. 8 has expanded;

FIG. 18 is an exemplary exploded sectional view showing a display of a portable computer as an example of an electronic apparatus according to a seventh embodiment;

FIG. 19 is an exemplary enlarged sectional view showing a first projection and a surrounding portion of a portable computer as an example of an electronic apparatus according to an eighth embodiment;

FIG. 20 is an exemplary enlarged sectional view showing a first projection and a surrounding portion of a portable computer as an example of an electronic apparatus according to a ninth embodiment;

FIG. 21 is an exemplary exploded perspective view showing a display of a portable computer as an example of an electronic apparatus according to a tenth embodiment;

FIG. 22 is an exemplary sectional view showing a first state in which a first main body of the portable computer shown in FIG. 21 has not expanded;

FIG. 23 is an exemplary exploded perspective view showing a display of a portable computer as an example of an electronic apparatus according to an eleventh embodiment;

FIG. 24 is an exemplary sectional view showing a first state in which a first main body of the portable computer shown in FIG. 23 has not expanded;

FIG. 25 is an exemplary enlarged perspective view showing a second projection on an upper side of a second member and a surrounding portion of a portable computer as an example of an electronic apparatus according to an twelfth embodiment;

FIG. 26 is an exemplary enlarged perspective view showing a second lower projection of the second member and a surrounding portion of the portable computer shown in FIG. 25;

FIG. 27 is an exemplary sectional view taken along a line F27-F27 shown in FIG. 25;

FIG. 28 is an exemplary sectional view showing a modification of the portable computer as the example of the electronic apparatus according to the sixth embodiment;

FIG. 29 is an exemplary sectional view showing a first modification of the portable computer as the example of the electronic apparatus according to the eleventh embodiment; and

FIG. 30 is an exemplary sectional view showing a second modification of the portable computer as the example of the electronic apparatus according to the eleventh embodiment.

### DETAILED DESCRIPTION

Various embodiments will be described hereinafter with reference to the accompanying drawings.

In general, according to one embodiment, an electronic apparatus includes a display panel, a first member, a second member, a pair of elastic bodies and a heating element. The first member includes a thermally expandable first main body surrounding a first face of the display panel, and a pair of first projections projecting from the first main body. The second member includes a second main body surrounding a second face of the display panel, and a pair of second projections projecting from the second main body to be located on inner sides of the first projections. Each of the elastic bodies is provided between a first projection and a second projection, and force the first main body outward before the first main body has thermally expanded and after the first main body has thermally expanded.

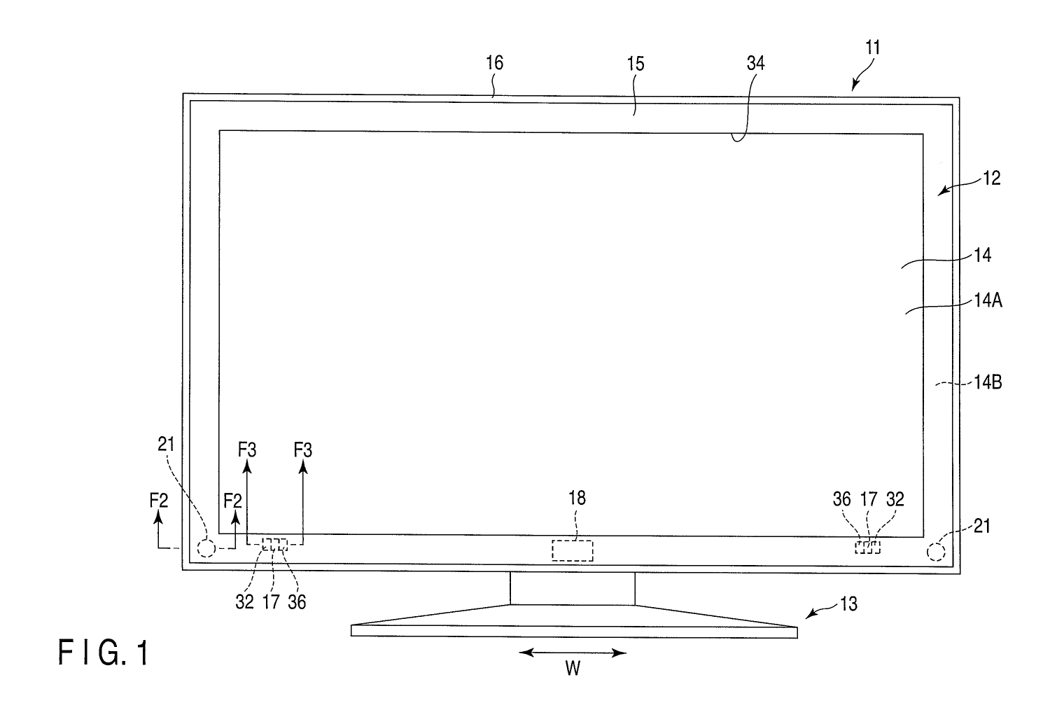

A television as an embodiment of an electronic apparatus will be described with reference to FIG. 1 to FIG. 3. As shown in FIG. 1, the television of this embodiment is a thin rectangular display apparatus. The television 11 shown in FIG. 1 comprises, for example, a display 12 and a stand (leg) 13 which supports the display 12.

The display 12 comprises a display panel (display device) 14, a first member (mask) 15 covering a first face (front face) 14A of the display panel 14, a second member (cover) 16 covering a second face (back face) 14B of the display panel 14, a pair of elastic bodies 17, each provided between a first projection 32 (described later) of the first member 15 and a second projection 36 (described later) of the second member 16, a light source 18 as an example of heating members (heating elements), fixing members 21 which fix the first member 15 and the second member 16, face plates 23 to conceal head portions 21A of the fixing members 21, a system board which is connected to the display panel 14 and controls the television 11 in its entirety, a tuner board and a power supply circuit board.

The first member 15 and the second member 16 form a casing as a shell of the television 11. The display panel 14 is formed of, for example, a liquid crystal panel shaped as a rectangular plate. The display panel 14 may be of any other type, for example, a plasma display panel or an organic EL panel. The light source 18 is an LED or the like, which functions as a backlight irradiating the liquid crystal panel with light from behind. The light source 18 is located in a position between paired first projections 32 (to be described later). The light source 18 is located in a position between the first member 15 and the second member 16 and generates heat when supplied with electricity.

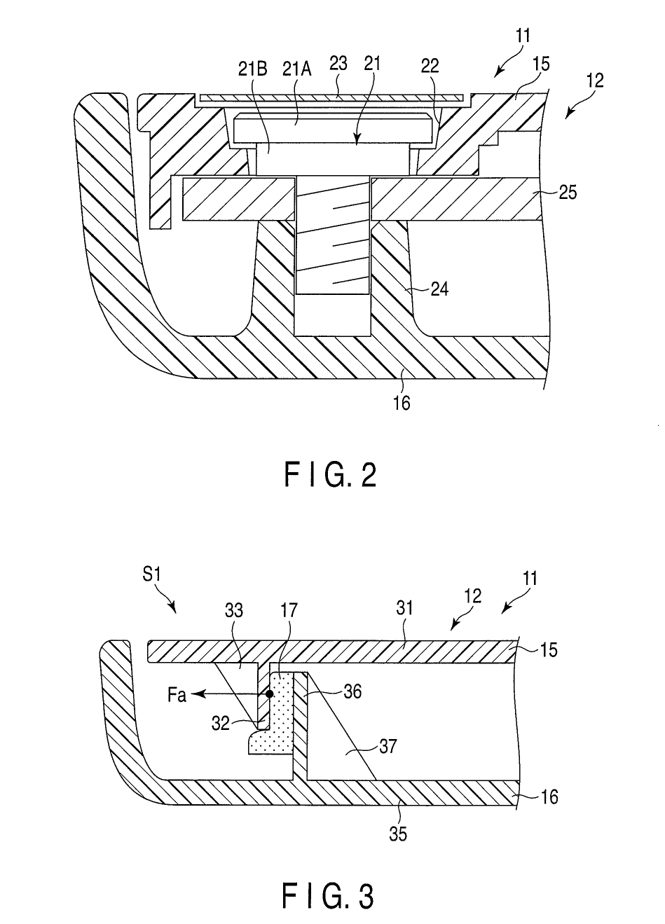

The fixing members 21 are stepped screws. As shown in FIG. 2, the head portion 21A and a stepped portion 21B of the fixing member 21 are fitted in a through hole 22 of the first member 15 with a play (clearance) therebetween. In other words, the fixing member 21 is movably fitted in the through hole 22. Therefore, even if the first member 15 thermally expands, the first member 15 can move outward even around the through hole 22, and cannot bend in a portion around the through hole 22. Further, as shown in FIG. 2, the fixing member 21 is connected to both a boss 24 provided in the second member 16 and a reinforcing plate 25.

The first member 15 is formed of a thermally expandable material, which has a high linear expansion coefficient, for example, a synthetic resin. The first member 15 comprises a first main body 31 which is frame-shaped to surround the first face 14A of the display panel 14, a pair of first projections 32 projecting from the first main body 31 in a direction crossing or perpendicular to a direction in which the first main body 31 extends, a pair of first ribs 33 to reinforce the first projections 32 and through holes 22 provided in the first main body 31. The first main body 31 has an opening 34 in a central portion thereof to expose the display panel 14. The distance between the first projections 32 is slightly smaller than the distance between an outer face of one elastic body 17 and an outer face of the other elastic body 17.

The second member 16 is formed of a thermally expandable material, which has a high linear expansion coefficient, for example, a synthetic resin. The second member 16 comprises a second main body 35 which covers the second face 14B of the display panel 14, a pair of second projections 36 projecting from the second main body 35 to be located on inner sides of the paired first projections 32 in a direction crossing or perpendicular to a direction in which the second main body 35 extends, and a pair of second ribs 37 to reinforce the second projections 36.

In this embodiment, the first projections 32 and the second projections 36 are disposed along a width direction W of the television 11, as shown in FIG. 1.

The elastic bodies 17 are respectively adhered to the second projections 36. The elastic bodies 17 are formed of, for example, sponge which exhibits elasticity like rubber, but may be formed of, for example, synthetic rubber, coil springs, or the like. The elastic body 17 is compressed between the first projection 32 and the second projection 36.

The first member 15 may thermally expand due to an influence of the light source 18 as a heating member. In this case, the elastic body 17 functions as follows. In a first state S1 in which the first member 15 has not thermally expanded as shown in FIG. 3, the elastic body 17 exerts force Fa on the first member 15 outward (in a direction to increase the distance between the first projections 32). In a second state S2 in which the first member 15 has thermally expanded, the elastic body 17 exerts force Fb on the first member 15 outward (in a direction to increase the distance between the first projections 32).

According to the first embodiment, the first members 15 can be pressed outward in both the first state S1 in which the first member 15 has not thermally expanded and the second state S2 in which the first member 15 has thermally expanded. Therefore, even when the first main body 31 has thermally expanded, the central portion of the first main body 31 will not rise and accordingly the first member 15 will not rise above the display panel 14. As a result, the appearance of the television 11 is kept attractive.

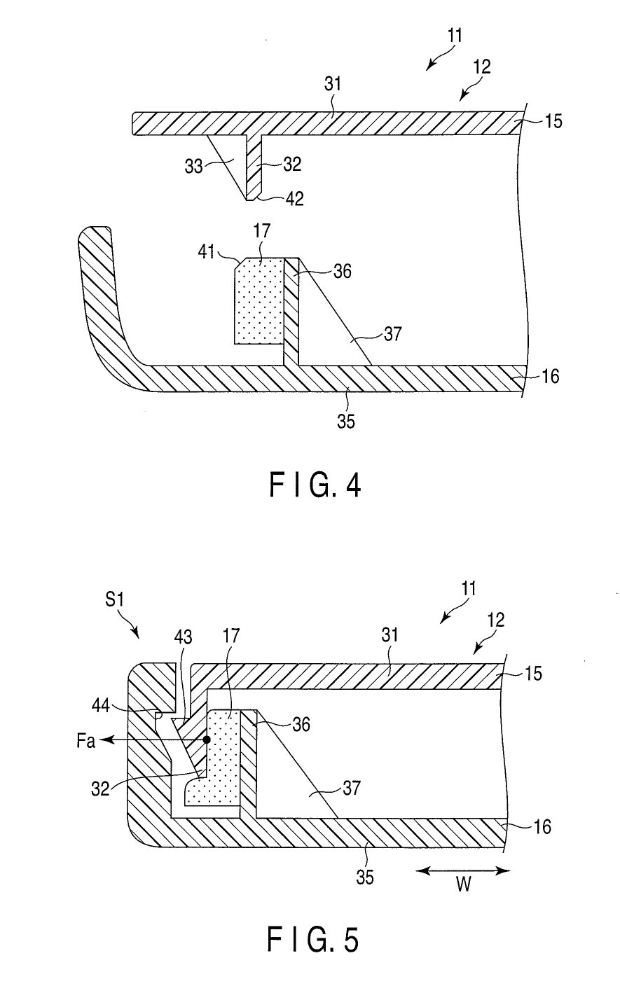

A second embodiment of an electronic apparatus will now be described with reference to FIG. 4. A television 11 as an example of the electronic apparatus of the second embodiment is the same as the first embodiment except for the structure of the first projections 32 and the elastic bodies 17. Therefore, parts different from those of the first embodiment will mainly be explained. The same parts are identified by the same reference symbols as those used for the first embodiment and the descriptions thereof are omitted. The television 11 of the second embodiment has the same exterior as that of the first embodiment shown in FIG. 1.

FIG. 4 shows an exploded view of the television 11 of the second embodiment. In the second embodiment, the first projections 32 of the first member 15 include slanted top ends 42. The top ends 42 are slanted such that the distance between the first projections 32 increases. Thus, the inner corners of the first projections 32 have been removed.

Elastic bodies 17 are respectively fixed to the second projections 36. The elastic members 17 have facing portions 41 which face the first projections 32. The facing portions 41 are slanted such that the distance between the elastic bodies 17 is reduced. Therefore, when the first member 15 is attached to the second member 16, the first projections 32 are prevented from abutting on side surfaces of the elastic bodies 17.

In this embodiment, the first projections 32 include the slanted top ends 42, the elastic bodies 17 include the facing portions 41 which face the first projections 32 and the facing portions 41 are slanted. Therefore, according to this embodiment, when the first member 15 is fixed to the second member 16, the first projections 32 can easily be inserted along the elastic bodies 17.

A third embodiment of an electronic apparatus will be described with reference to FIG. 5. A television 11 as an example of the electronic apparatus of the third embodiment is the same as the first embodiment except for the structure of the first projections 32. Therefore, parts different from those in the first embodiment will mainly be explained. The same parts are identified by the same reference symbols as those used for the first embodiment and the descriptions thereof are omitted. The television 11 of the second embodiment has the same exterior as that of the first embodiment shown in FIG. 1.

The first projections 32 are provided at the ends in the width direction W of the first member 15. The first projection 32 has an engagement portion 43 which engages with the second member 16. The second member 16 is provided with a receiving portion 44 recessed from an inner surface of the second main body 35. The engagement portion 43 of the first projection 32 is shaped like a hook and can be fitted in the receiving portion 44 of the second member 16 and engages with the second member 16. The elastic body 17 can exert not only force Fa on the first member 15 outward in the first state in which the first member 15 has not thermally expanded but also exert force Fb on the first member 15 outward in the second state in which the first member 15 has thermally expanded.

According to the third embodiment, the first projection 32 has the engagement portion 43 for engagement with the second member 16. With this configuration, the first projection 32 has both the function of forcing the first member 15 outward and the function performed by the engagement member 43. Thus, the structure can be more simplified as compared to the case in which different members have the two functions.

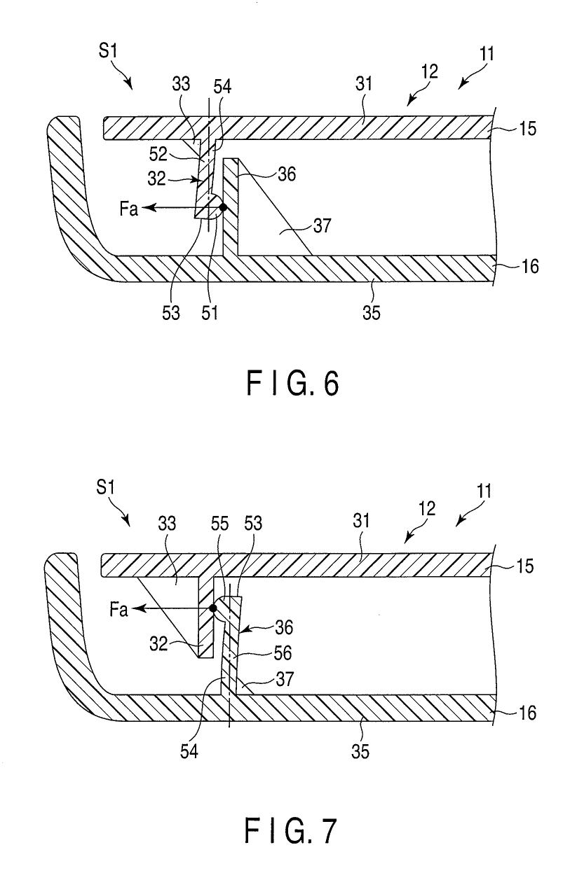

A fourth embodiment of an electronic apparatus will now be described with reference to FIG. 6. A television 11 as an example of the electronic apparatus of the fourth embodiment is the same as the first embodiment except that a pair of elastic bodies 17 are not provided. Therefore, parts different from those in the first embodiment will mainly be explained. The same parts are identified by the same reference symbols as those used for the first embodiment and the descriptions thereof are omitted. The television 11 of the fourth embodiment has the same exterior as that of the first embodiment shown in FIG. 1.

The first projection 32 is configured to exhibit elasticity when it is brought into contact with the second projection 36. More specifically, the first projection 32 has a first contact portion 51 projecting toward the second projection 36 to be in contact with the second projection 36, and a first support portion 52 which supports the first contact portion 51 and exhibits elasticity. The first rib 33 is smaller than that of the first embodiment so as not to interfere with the elasticity of the first projection 32. It reinforces only a proximal end 54 opposite to a distal end 53 of the first projection 32.

In this embodiment, the first member 15 is fixed to the second member 16 to assemble the television 11, while the first projection 32 is forced and extended outward by, for example, a finger or a jig, so that the first contact portion 51 of the first projection 32 abuts against the second projection 36.

Because of the elasticity, the first projection 32 can exert not only force Fa on the first member 15 outward in the first state S1 in which the first member 15 has not thermally expanded but also exert force Fb on the first member 15 outward in the second state S2 in which the first member 15 has thermally expanded. The first member 15 expands for example, about 0.2 to 0.3 mm by thermal expansion. In this embodiment, the first projection 32 has a stroke of about 0.2 to 0.3 mm corresponding to the thermal expansion of the first member 15.

According to this embodiment, the first projection 32 and the second projection 36 are in direct contact with each other by the elasticity of the first projection 32. With this configuration, since the elastic bodies 17 can be omitted, the number of parts can be reduced, resulting in reduction of manufacturing costs.

In this embodiment, the first main body 31 and the first projection 32 of the first member 15 are integrally formed of synthetic resin or the like. However, the first projection 32 may be formed of a metal part to provide elasticity. In this case, the first projection 32 formed of the metal part can be fixed to the first main body 31 made of the synthetic resin or the like by an adhesive or screw.

A fifth embodiment of an electronic apparatus will now be described with reference to FIG. 7. A television 11 as an example of the electronic apparatus of the fifth embodiment is the same as the first embodiment except that a pair of elastic bodies 17 are not provided. Therefore, parts different from those in the first embodiment will mainly be explained. The same parts are identified by the same reference symbols as those used for the first embodiment and the descriptions thereof are omitted. The television 11 of the fifth embodiment has the same exterior as that of the first embodiment shown in FIG. 1.

In this embodiment, the second projection 36 is configured to exhibit elasticity. More specifically, the second projection 36 has a second contact portion 55 projecting toward the first projection 32 to be in contact with the first projection 32, and a second support portion 56 which supports the second contact portion 55 and exhibits elasticity. The second rib 37 is smaller than that of the first embodiment so as not to interfere with the elasticity of the second projection 36. It reinforces only a proximal end 54 opposite to a distal end 53 of the second projection 36.

In this embodiment, the first member 15 is fixed to the second member 16 to assemble the television 11, while the second projection 36 is forced and bent inward by, for example, a finger or a jig, so that the second contact portion 55 of the second projection 36 abuts against the first projection 32.

Because of the elasticity, the second projection 36 can exert not only force Fa on the first member 15 outward in the first state S1 in which the first member 15 has not thermally expanded but also exert force Fb on the first member 15 outward in the second state S2 in which the first member 15 has thermally expanded. The first member 15 expands for example, about 0.2 to 0.3 mm by thermal expansion. In this embodiment, the second projection 36 has a stroke of about 0.2 to 0.3 mm corresponding to the thermal expansion of the first member 15.

According to this embodiment, the first projection 32 and the second projection 36 are in direct contact with each other by the elasticity of the second projection 36. With this configuration, since the elastic bodies 17 are not required, the number of parts can be reduced, resulting in reduction of manufacturing costs.

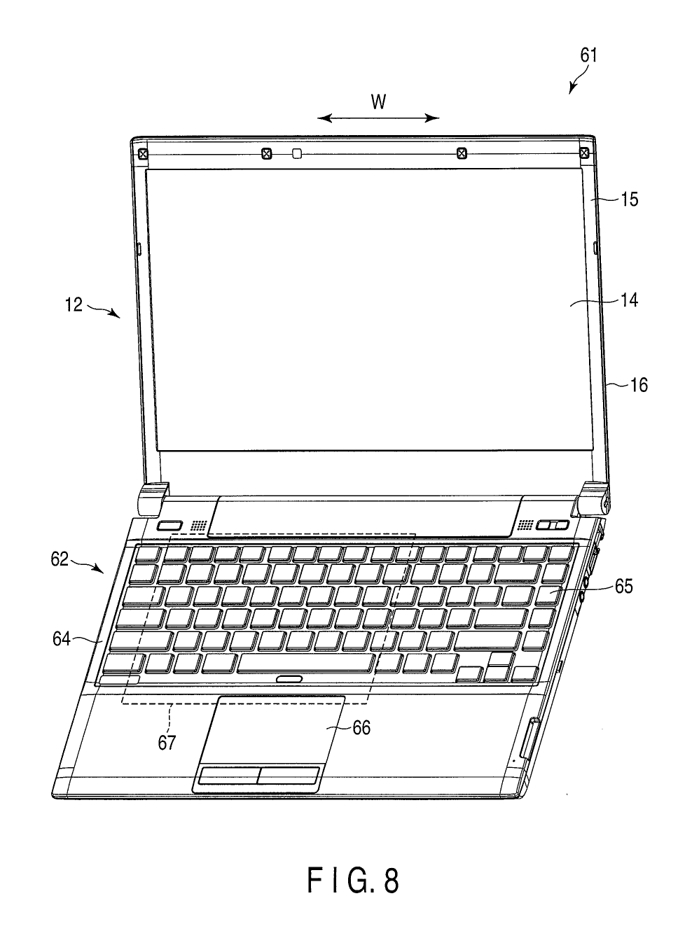

A sixth embodiment of an electronic apparatus will now be described with reference to FIG. 8 to FIG. 17. A portable computer 61 as an example of the electronic apparatus of the sixth embodiment differs from the television 11 of the first embodiment in appearance, but the structure around a display panel 14 is substantially the same as that of the first embodiment. Therefore, parts different from those in the first embodiment will mainly be explained. The same parts are identified by the same reference symbols as those used for the first embodiment and the descriptions thereof are omitted.

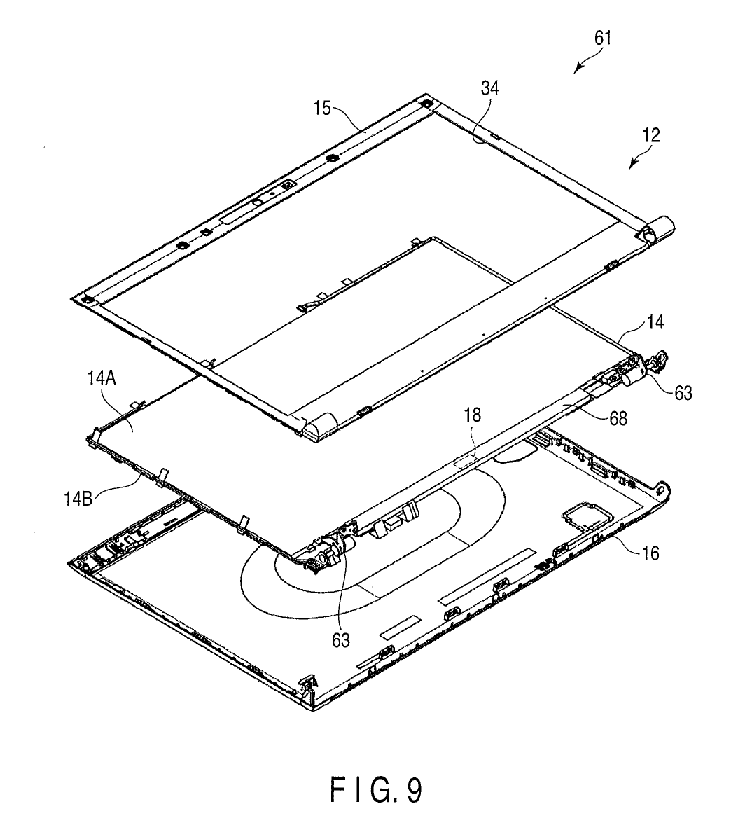

As shown in FIG. 8 and FIG. 9, the portable computer 61 comprises a main body 62, a display 12 which can lie over the main body 62 and stand upright with respect to the main body 62, and hinges 63 provided between the main body 62 and the display 12. The main body 62 comprises, for example, a case 64 as a shell, a keyboard 65 and a touch pad 66 attached to the case 64, and a print circuit board (mother board) 67 contained inside the case 64. The print circuit board 67 controls the portable computer 61 in its entirety.

As shown in FIG. 8 to FIG. 14, the display 12 comprises a display panel (display device) 14, a first member (mask) 15 covering a first face (front face) 14A of the display panel 14, a second member (cover) 16 covering a second face (back face) 14B of the display panel 14, a pair of elastic bodies 17 each provided between a first projection 32 (described later) of the first member 15 and a second projection 36 (described later) of the second member 16, a control board 68 which controls the display panel 14, a light source 18 as an example of heating members (heating elements) which is included the control board 68, fixing members 21 which fix the first member 15 and the second member 16, face plates 23 to conceal head portions 21A of the fixing members 21, and metal fittings 71 integral with the hinges 63.

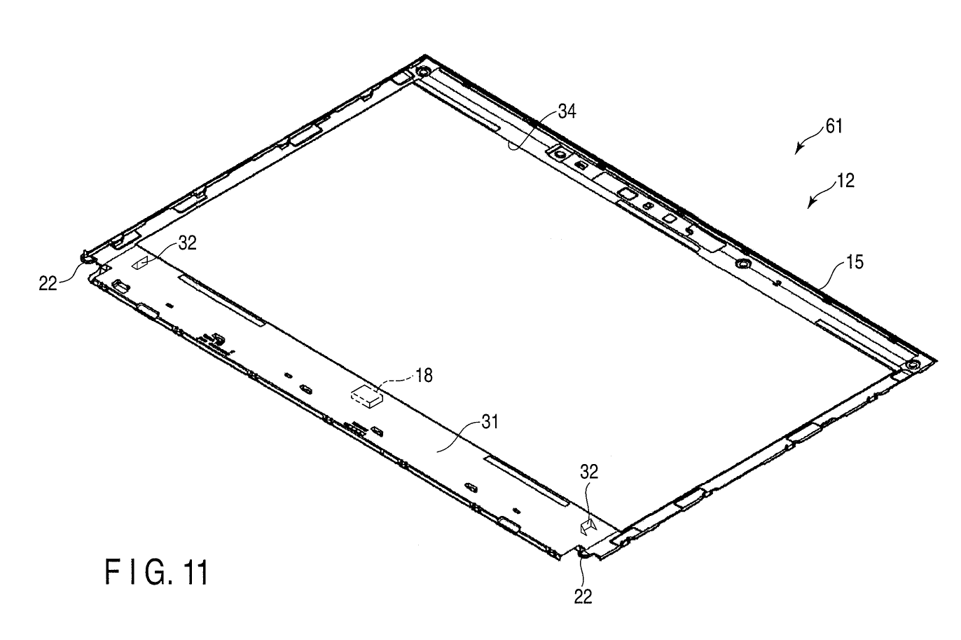

As shown in FIG. 9, the first member 15 and the second member 16 form a casing as a shell of the display 12. In this embodiment, the display panel 14 is formed of, for example, a liquid crystal panel shaped as a rectangular plate. The display panel 14 may be of any other type, for example, a plasma display panel and an organic EL panel. The light source 18 is an LED or the like, which functions as a backlight irradiating the liquid crystal panel with light from behind. As shown in FIG. 11, the light source 18 is located between the paired first projections 32. The light source 18 is located in a position between the first member 15 and the second member 16 and generates heat when supplied with electricity.

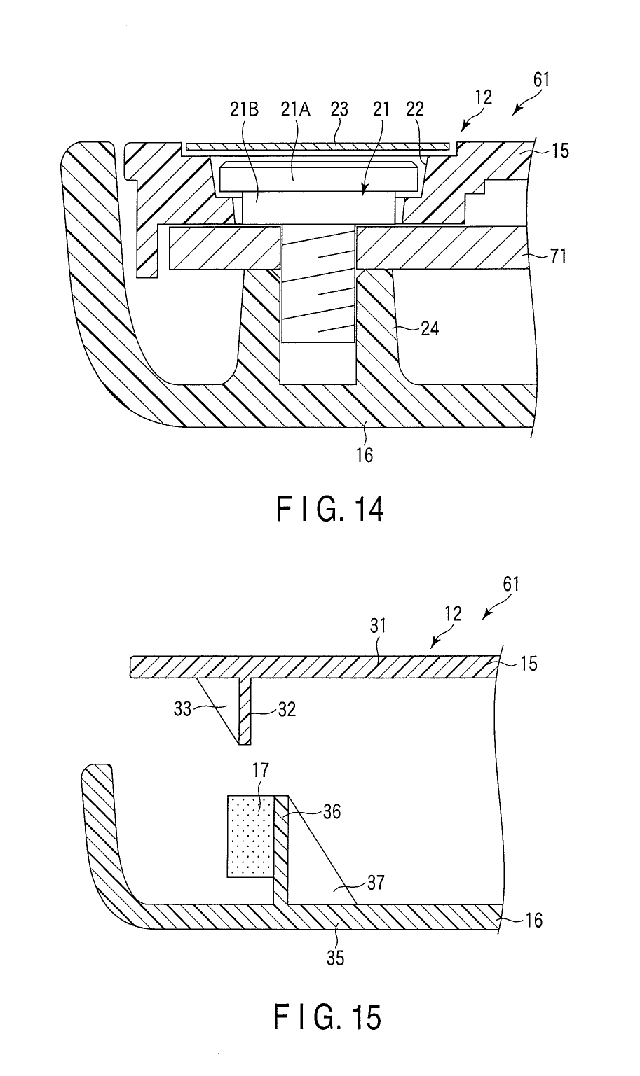

As shown in FIG. 14, the fixing members 21 are stepped screws. The head portion 21A and a stepped portion 21B of the fixing member 21 are fitted in a through hole 22 of the first member 15 with a play (clearance) therebetween. In other words, the fixing member 21 is movably fitted in the through hole 22. Therefore, even if the first member 15 thermally expands, the first member 15 can move outward even around the through hole 22, and will not bend in a portion around the through hole 22. Further, as shown in FIG. 14, the fixing member 21 is connected to both a boss 24 provided in the second member 16 and the metal fitting 71 integral with the hinge portion 63. The fixing member 21 fixes not only the first member 15 and the second member 16 but also the metal fittings 71 to the second member 16.

The first member 15 is formed of a thermally expandable material, which has a high linear expansion coefficient, for example, a synthetic resin. As shown in FIG. 11 to FIG. 13 and FIG. 16, the first member 15 comprises a first main body 31 which is frame-shaped to surround the first face 14A of the display panel 14, a pair of first projections 32 projecting from the first main body 31 in a direction crossing or perpendicular to a direction in which the first main body 31 extends, a pair of first ribs 33 to reinforce the first projections 32 and through holes 22 provided in the first main body 31. As shown in FIG. 11, the first main body 31 has an opening 34 in a central portion thereof to expose the display panel 14. The distance between the first projections 32 is slightly smaller than the distance between an outer face of one elastic body 17 and an outer face of the other elastic body 17.

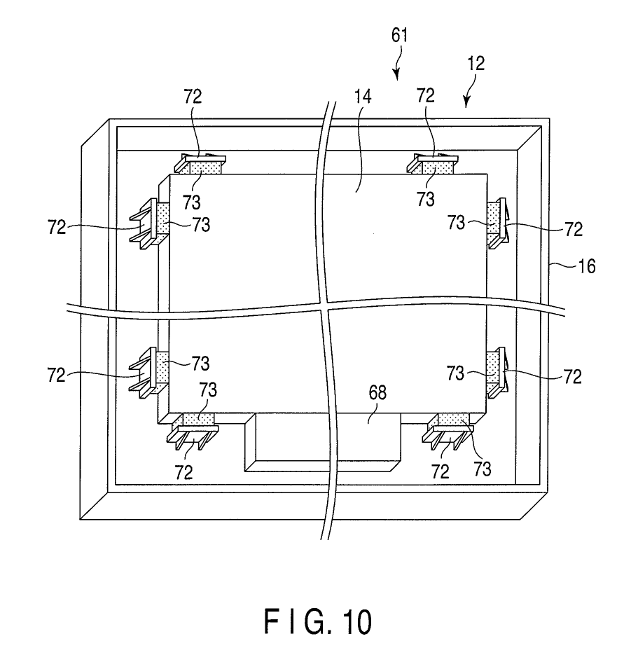

The second member 16 is formed of a thermally expandable material, which has a high linear expansion coefficient, for example, a synthetic resin. As shown in FIG. 9, FIG. 10 and FIG. 12 to FIG. 16, the second member 16 comprises a second main body 35 which surrounds the second face 14B of the display panel 14, a plurality of retainers 72 to fixedly hold the four corners of the display panel 14, a pair of second projections 36 projecting from the second main body 35 to be located on inner sides of the paired first projections 32 in a direction crossing or perpendicular to a direction in which the second main body 35 extends, and a pair of second ribs 37 to reinforce the second projections 36. As shown in FIG. 10, the retainers 72 are provided around the display panel 14. Elastic members (sponges) 73 are respectively fixed to the retainers 72 to elastically retain the display panel 14. The elastic members 73 may be synthetic resin, coil springs or the like.

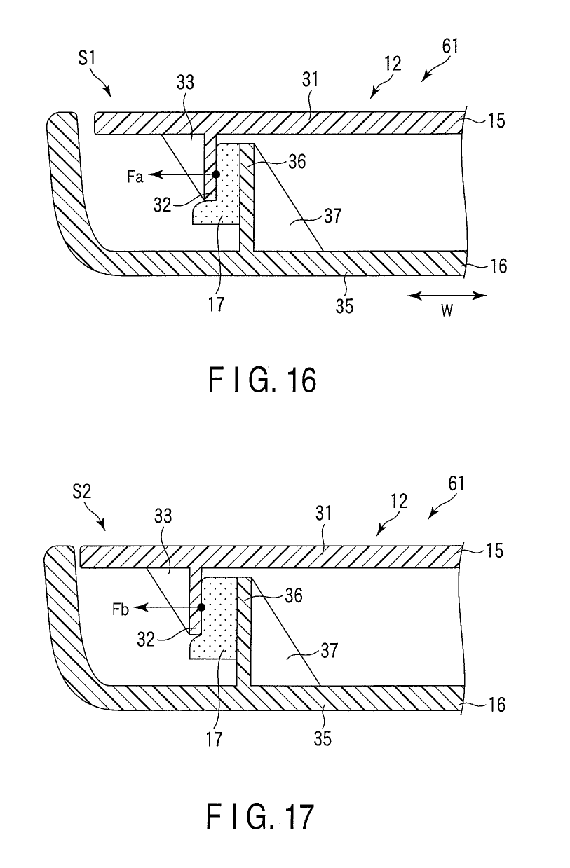

In this embodiment, the first projections 32 and the second projections 36 are disposed along a width direction W of the portable computer 61, as shown in FIG. 8 and FIG. 16.

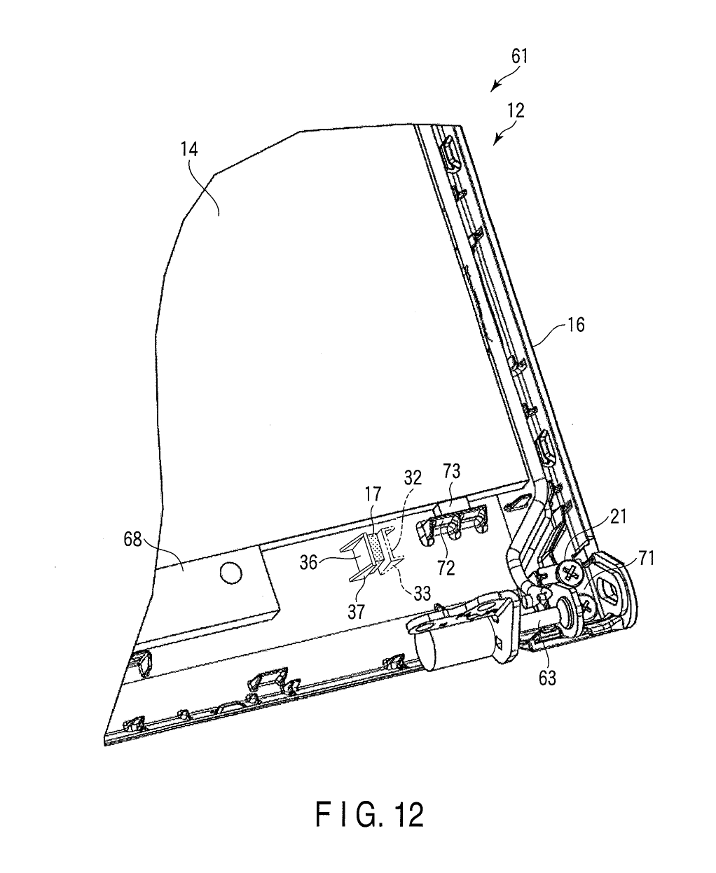

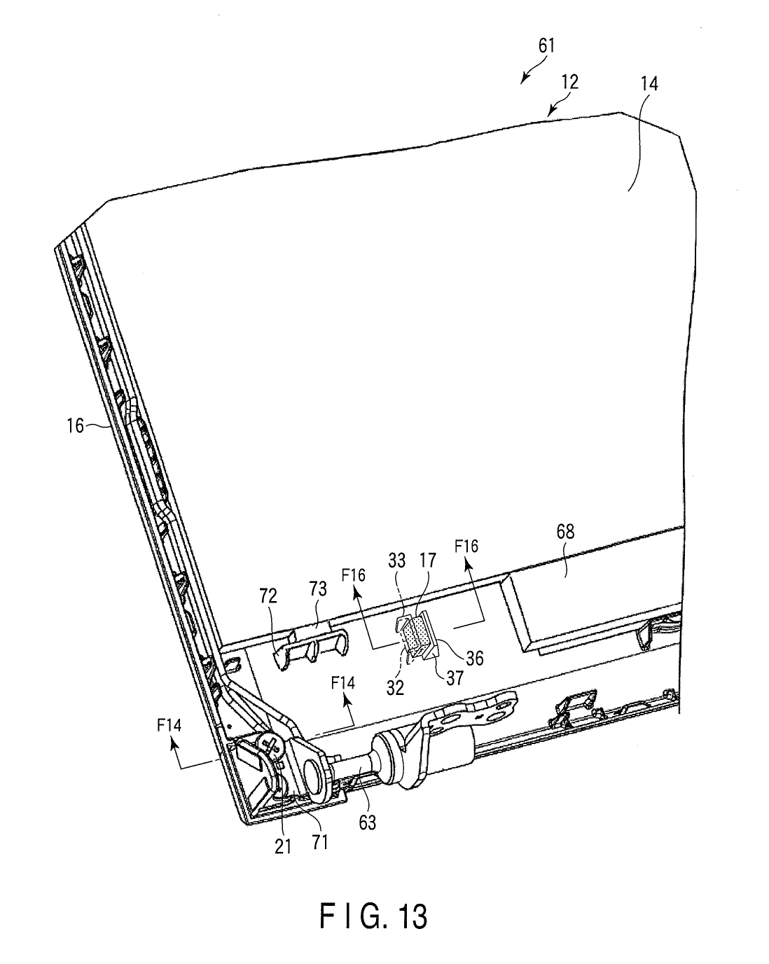

As shown in FIG. 12 and FIG. 13, the elastic bodies 17 are respectively adhered to the second projections 36. The elastic bodies 17 are formed of, for example, sponge which exhibits elasticity like rubber. The elastic bodies 17 may be formed of, for example, synthetic rubber, coil springs, or the like. The elastic body 17 is compressed between the first projection 32 and the second projection 36.

To assemble the display 12, first, the display panel 14 is fixed to the second member 16, as shown in FIG. 15 and FIG. 16. Then the first member 15 is fixed to the second member 16 with the elastic body 17 compressed between the first projection 32 and the second projection 36. Thus, the assembly of the display 12 is completed.

The first member 15 may thermally expand due to an influence of the light source 18 as a heating member. In this case, the elastic body 17 functions as follows. In a first state S1 in which the first member 15 has not thermally expanded as shown in FIG. 16, the elastic body 17 exerts force Fa on the first member 15 outward (in a direction to increase the distance between the first projections 32). In a second state S2 in which the first member 15 has thermally expanded as shown in FIG. 17, the elastic body 17 exerts force Fb on the first member 15 outward (in a direction to increase the distance between the first projections 32).

According to the sixth embodiment, the portable computer 61 comprises: the display panel 14; the first member 15 comprising the first main body 31 which is thermally expandable and surrounds the first face 14A of the display panel 14 and the pair of first projections 32 projecting from the first main body 31; the second member 16 comprising the second main body 35 which surrounds the second face 14B of the display panel 14 and the pair of second projections 36 projecting from the second main body 35 to be located on inner sides of the paired first projections 32, the pair of elastic bodies 17 which are respectively provided between one of the first projections 32 and one of the second projections 36 and between the other of the first projections 32 and the other of the second projections 36 and which exert force on the first main body 31 outward in both the first state S1 in which the first main body 31 has not thermally expanded and the second state S2 in which the first main body has thermally expanded; and the heating member which changes the first main body 31 between the first state S1 and the second state S2.

With this configuration, the elastic bodies 17 can exert force on the first main body 31 of the first member 15 outward in both the first state S1 in which the first main body 31 has not thermally expanded and the second state S2 in which the first main body has thermally expanded. Therefore, the simple structure using the elastic bodies can prevent the central portion of the first main body 31 from rising even when the first main body 31 thermally expanded and accordingly prevent the first member 15 from separating above the display panel 14. As a result, the appearance of the television 11 is kept attractive.

Further, the heating member is disposed between the paired first projections 32. Therefore, even when thermal expansion of the first main body 31 occurs around the heating member, the first member 15 is prevented from separating above the display panel 14 around the heating member. As a result, the first projections 32, the second projections 36 and the elastic bodies 17 can fully perform their functions.

The portable computer 61 comprises through holes 22 provided in the first main body 31 near the respective first projections 32, and fixing members 21 which are fitted in the through holes 22 with a play (clearance) therebetween and fix the first member 15 to the second member 16. With this configuration, since the first member 15 is fixed by the fixing members 21 with a play, even if the first member 15 thermally expands, it will not bend in a portion around the fixing members 21. Therefore, the structure of the through holes and the fixing members, in addition to the first projections 32, the second projections 36 and the elastic bodies 17, can more effectively prevent the first member 15 from separating above the display panel 14.

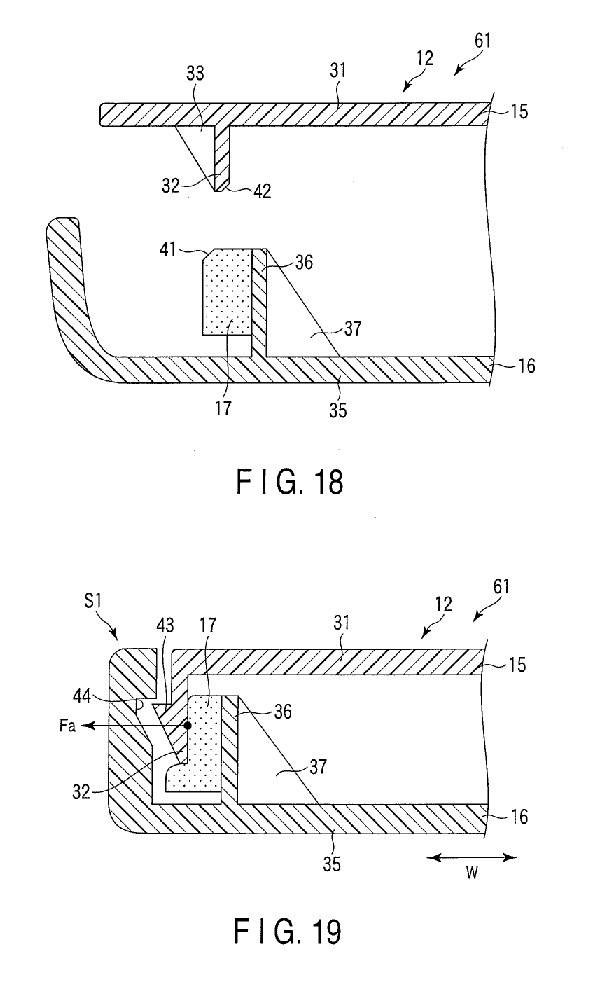

A seventh embodiment of an electronic apparatus will now be described with reference to FIG. 18. A portable computer 61 as an example of the electronic apparatus of the seventh embodiment is the same as the sixth embodiment except for the structure of the first projections 32 and the elastic bodies 17. Therefore, parts different from those in the sixth embodiment will mainly be explained. The same parts are identified by the same reference symbols as those used for the sixth embodiment and the descriptions thereof are omitted. The portable computer 61 of this embodiment has the same exterior as that of the sixth embodiment shown in FIG. 8.

FIG. 18 shows an exploded view of a display 12 of the portable computer 61. First projections 32 of a first member 15 have slanted top ends 42. In this embodiment, inner corner portions of the first projection 32 have been removed and the remaining parts form the top ends 42. Because of the top ends 42 of the first projections 32, the distance between the first projections 32 substantially increases.

The elastic bodies 17 are respectively fixed to the second projections 36. The elastic members 17 have facing portions 41 which face the first projections 32. The facing portions 41 are slanted with respect to the top surfaces of the elastic bodies 17. Thus, in this embodiment, the corner portions of the elastic bodies 17, that face the first projections 32, have been removed to form the facing portions 41. As a result, the distance between the paired elastic bodies 17 is substantially smaller than that of the sixth embodiment.

The provision of the top ends 42 and the facing portions 41 prevents the first projections 32 from abutting on side surfaces of the elastic bodies 17, when the first member 15 is attached to the second member 16. Thus, the elastic bodies 17 can easily be arranged in a compressed state.

In this embodiment, the elastic bodies 17 are respectively fixed to the second projections 36, and the first projections 32 have the top ends 42, which are slanted such that the distance between the first projections 32 increases. The elastic bodies 17 have the facing portions 41 which face the first projections 32. The facing portions 41 are slanted such that the distance between the paired elastic bodies 17 is reduced. Because of these configurations, when the first member 15 is attached to the second member 16, the first projections 32 are prevented from abutting on the elastic bodies 17. Thus, the first projections can easily be inserted along the elastic bodies 17. As a result, the workability in assembling the portable computer 61 is improved.

An eighth embodiment of an electronic apparatus will now be described with reference to FIG. 19. A portable computer 61 as an example of the electronic apparatus of the eighth embodiment is the same as the sixth embodiment except for the structure of the first projections 32. Therefore, parts different from those in the sixth embodiment will mainly be explained. The same parts are identified by the same reference symbols as those used for the sixth embodiment and the descriptions thereof are omitted. The portable computer 61 of this embodiment has the same exterior as that of the sixth embodiment shown in FIG. 8.

In this embodiment, the first projections 32 are provided at the ends in the width direction W of the first member 15. The first projection 32 has an engagement portion 43 which engages with the second member 16. The second member 16 is provided with a receiving portion 44 recessed from an inner surface of the second main body 35. The engagement portion 43 of the first projection 32 is shaped like a hook and can be fit in the receiving portion 44 of the second member 16 and engages with the second member 16. As shown in FIG. 19, the elastic body 17 can exert not only force Fa on the first member 15 outward in a first state S1 in which the first member 15 has not thermally expanded but also exert force Fb on the first member 15 outward in a second state S2 in which the first member 15 has thermally expanded.

According to the eighth embodiment, the first projection 32 has the engagement portion 43 for engagement with the second member 16. With this configuration, the first projection 32 has both the function of forcing the first member 15 outward and the function of engaging the second member 16 with the first projections 32. Thus, the structure can be more simplified as compared to the case in which the first projections 32 and engagement members 43 are separately provided.

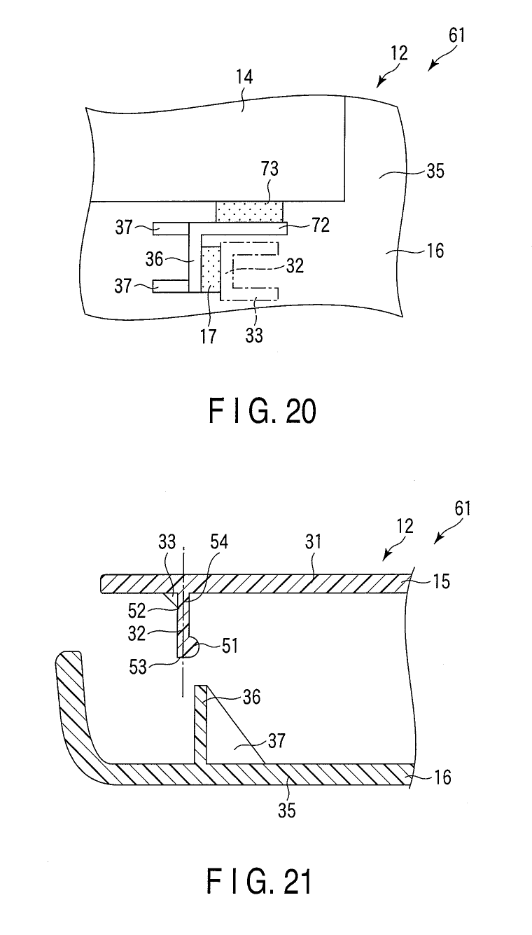

A ninth embodiment of an electronic apparatus will now be described with reference to FIG. 20. A portable computer 61 as an example of the electronic apparatus of the ninth embodiment is the same as the sixth embodiment except for the structure of the second projections 36. Therefore, parts different from those in the sixth embodiment will mainly be explained. The same parts are identified by the same reference symbols as those used for the sixth embodiment and the descriptions thereof are omitted. The portable computer 61 of this embodiment has the same exterior as that of the sixth embodiment shown in FIG. 8.

A second projection 36 is formed integral with one of a plurality of retainers 72. More specifically, the second projection 36 and the retainer 72 form an L shape.

According to the ninth embodiment, the second member 16 comprises the plurality of retainers 72 which retains a display panel 14, and each of the second projections 36 is integral with one of the retainers 72. With this configuration, the second projection 36 need not be provided independent of the retainer 72, so that the overall structure can be simplified.

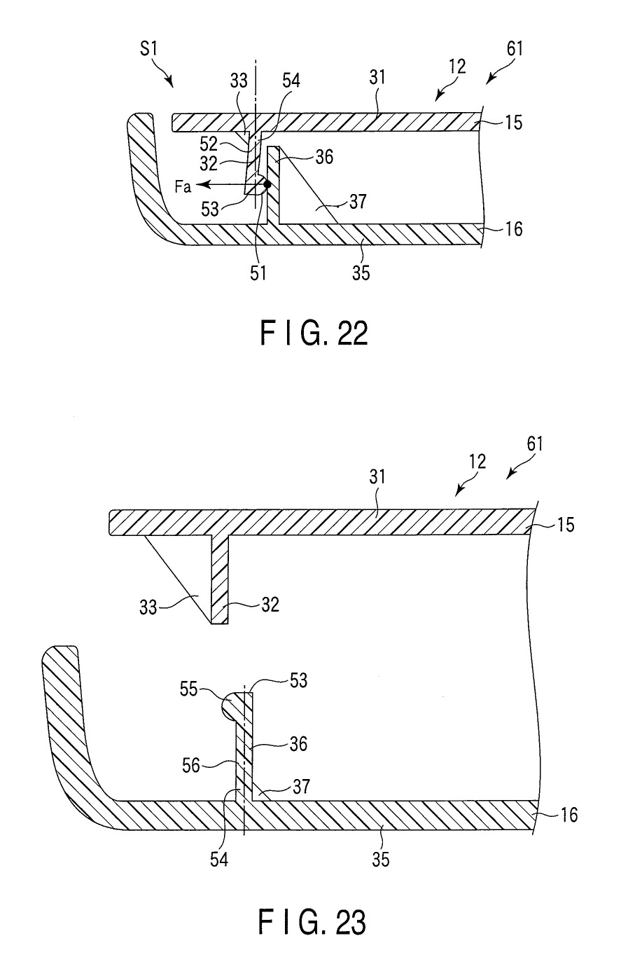

A tenth embodiment of an electronic apparatus will now be described with reference to FIG. 21 and FIG. 22. A portable computer 61 as an example of the electronic apparatus of the tenth embodiment is the same as the sixth embodiment except that a pair of elastic bodies 17 are not provided. Therefore, parts different from those in the sixth embodiment will mainly be explained. The same parts are identified by the same reference symbols as those used for the first embodiment and the descriptions thereof are omitted. The portable computer 61 of this embodiment has the same exterior as that of the sixth embodiment shown in FIG. 8.

In this embodiment, the first projection 32 is configured to exhibit elasticity when it is brought into contact with the second projection 36. More specifically, the first projection 32 has a first contact portion 51 projecting toward the second projection 36 to be in contact with the second projection 36, and a first support portion 52 which supports the first contact portion 51 and exhibits elasticity. The first rib 33 is smaller than that of the sixth embodiment so as not to interfere with the elasticity of the first projection 32. It reinforces only a proximal end 54 opposite to a distal end 53 of the first projection 32.

In this embodiment, the first member 15 is fixed to the second member 16 to assemble the portable computer 61, while the first projection 32 is forced and extended outward by, for example a finger or a jig, so that the first contact portion 51 of the first projection 32 abuts against the second projection 36.

Because of the elasticity, the first projection 32 can exert not only force Fa on the first member 15 outward in the first state S1 in which the first member 15 has not thermally expanded but also force Fb on the first member 15 outward in the second state S2 in which the first member 15 has thermally expanded. The first member 15 expands for example, about 0.2 to 0.3 mm by thermal expansion. In this embodiment, the first projection 32 has a stroke of about 0.2 to 0.3 mm corresponding to the thermal expansion of the first member 15.

According to this embodiment, the first projection 32 and the second projection 36 are in direct contact with each other by the elasticity of the first projection 32. With this configuration, since the elastic bodies 17 can be omitted, the number of parts can be reduced, resulting in reduction of manufacturing costs.

In this embodiment, the first main body 31 and the first projection 32 of the first member 15 are integrally formed of synthetic resin or the like. However, the first projection 32 may be formed of a metal part to provide elasticity. In this case, the first projection 32 formed of the metal part can be fixed to the first main body 31 formed of the synthetic resin or the like by an adhesive or screw.

According to the tenth embodiment, the portable computer 61 comprises a display panel 14; a first member 15 which has a thermally expandable first main body 31 covering a first face 14A of the display panel 14 and has a pair of first projections 32 projecting from the first main body 31; a second member 16 which has a second main body 35 covering a second face 14B of the display panel 14 and has a pair of second projections 36 projecting from the second main body 35 to be located on inner sides of the paired first projections 32; and a heating element which changes the first main body 31 between a first state S1 in which the first main body 31 has not thermally expanded and a second state S2 in which the first main body 31 has thermally expanded, the pair of first projections 32 having elasticity which forces the first main body 31 outward in both the first state S1 and the second state S2.

With this configuration, since the elastic bodies 17 can be omitted, the number of parts can be reduced, resulting in reduction of manufacturing costs, as compared to the sixth embodiment.

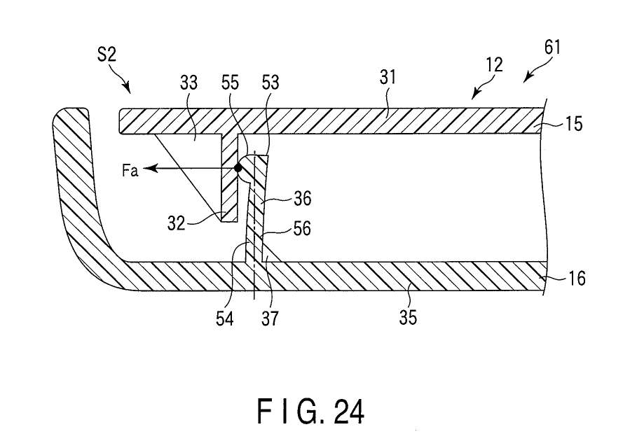

An eleventh embodiment of an electronic apparatus will be described with reference to FIG. 23 and FIG. 24. A portable computer 61 as an example of the electronic apparatus of the eleventh embodiment is the same as the sixth embodiment except that a pair of elastic bodies 17 are not provided. Therefore, parts different from those in the sixth embodiment will mainly be explained. The same parts are identified by the same reference symbols as those used for the sixth embodiment and the descriptions thereof are omitted. The portable computer 61 of the eleventh embodiment has the same exterior as that of the sixth embodiment shown in FIG. 8.

In this embodiment, the second projection 36 is configured to exhibit elasticity. More specifically, the second projection 36 has a second contact portion 55 projecting toward the first projection 32 to be in contact with the first projection 32, and a second support portion 56 which supports the second contact portion 55 and exhibits elasticity. The second rib 37 is smaller than that of the first embodiment so as not to interfere with the elasticity of the second projection 36. It reinforces only a proximal end 54 opposite to a distal end 53 of the second projection 36.

In this embodiment, the first member 15 is fixed to the second member 16 to assemble the portable computer 61, while the second projection 36 is forced and bent inward by, for example, a finger or a jig, so that the second contact portion 55 of the second projection 36 abuts against the first projection 32.

Because of the elasticity, the second projection 36 can exert not only force Fa on the first member 15 outward in the first state S1 in which the first member 15 has not thermally expanded but also force Fb on the first member 15 outward in the second state S2 in which the first member 15 has thermally expanded. The first member 15 expands, for example, about 0.2 to 0.3 mm by thermal expansion. In this embodiment, the second projection 36 has a stroke of about 0.2 to 0.3 mm corresponding to the thermal expansion of the first member 15.

According to this embodiment, the first projection 32 and the second projection 36 are in direct contact with each other by the elasticity of the second projection 36. With this configuration, since the elastic bodies 17 can be omitted, the number of parts can be reduced, resulting in reduction of manufacturing costs.

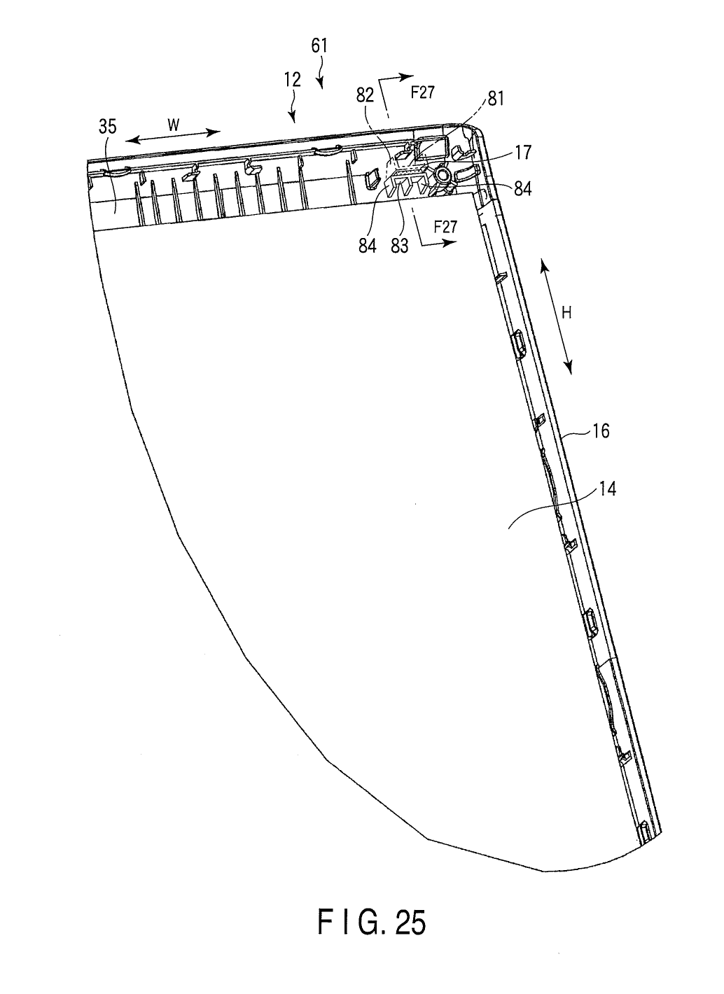

A twelfth embodiment of an electronic apparatus will now be described with reference to FIG. 25 to FIG. 27. A portable computer 61 as an example of the electronic apparatus of the twelfth embodiment is the same as the sixth embodiment except for the direction in which the first projections 32 and the second projections 36 are disposed. Therefore, parts different from those in the sixth embodiment will mainly be explained. The same parts are identified by the same reference symbols as those used for the sixth embodiment and the descriptions thereof are omitted. The portable computer 61 of this embodiment has the same exterior as that of the sixth embodiment shown in FIG. 8.

The first member 15 is formed of a thermally expandable material, which has a high linear expansion coefficient, for example, a synthetic resin. The first member 15 comprises a first main body 31 which is frame-shaped to surround the first face 14A of the display panel 14, a pair of first projections 81 projecting from the first main body 31 in a direction crossing or perpendicular to a direction in which the first main body 31 extends, a pair of first ribs 82 to reinforce the first projections 81 and through holes 22 provided in the first main body 31.

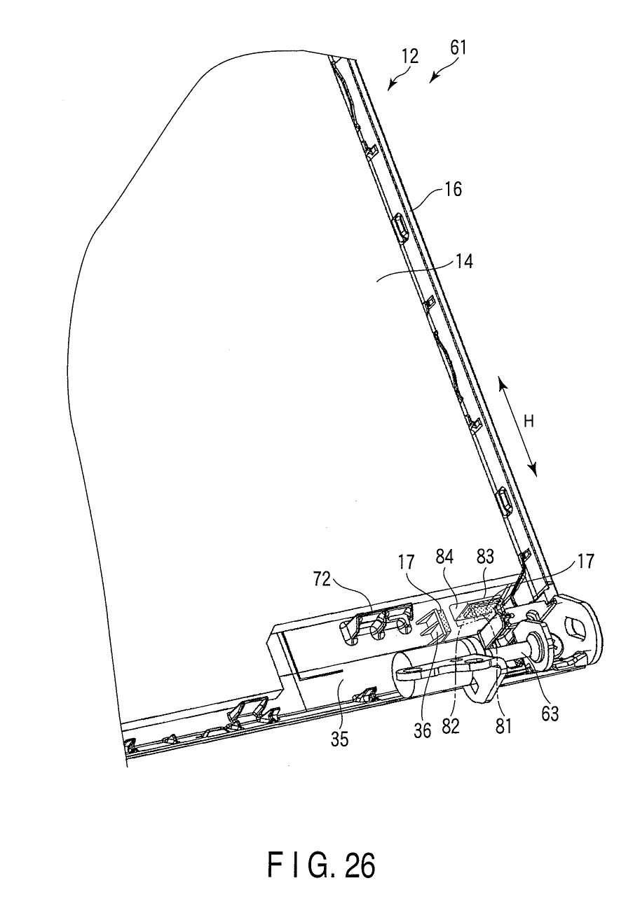

The second member 16 is formed of a thermally expandable material, which has a high linear expansion coefficient, for example, a synthetic resin. As shown in FIG. 25 and FIG. 26, the second member 16 comprises a second main body 35 which surrounds the second face 14B of the display panel 14, a plurality of retainers 72 to fixedly hold the four corners of the display panel 14, a pair of second projections 83 projecting from the second main body 35 to be located on inner sides of the paired first projections 81 in a direction crossing or perpendicular to a direction in which the second main body 35 extends, and a pair of second ribs 84 to reinforce the second projections 83. As shown in FIG. 26, the retainers 72 are provided around the display panel 14. Elastic members (sponges) 73 are respectively fixed to the retainers 72 to elastically retain the display panel 14. The elastic members 73 may be synthetic resin, coil springs or the like.

As shown in FIG. 25 and FIG. 26, the elastic bodies 17 are respectively adhered to the second projections 83. The elastic bodies 17 are formed of, for example, sponge which exhibits elasticity like rubber. The elastic bodies 17 may be formed of, for example, synthetic rubber, coil springs, or the like. The elastic body 17 is compressed between the first projection 81 and the second projection 83.

In this embodiment, the first projections 81 and the second projections 83 are disposed along a height direction H perpendicular to a width direction W of the portable computer 61, as shown in FIG. 25. Further, as shown in FIG. 26, this embodiment also includes first projections and second projections 36 disposed along the width direction W of the portable computer 61 and elastic bodies 17, as well as the sixth embodiment.

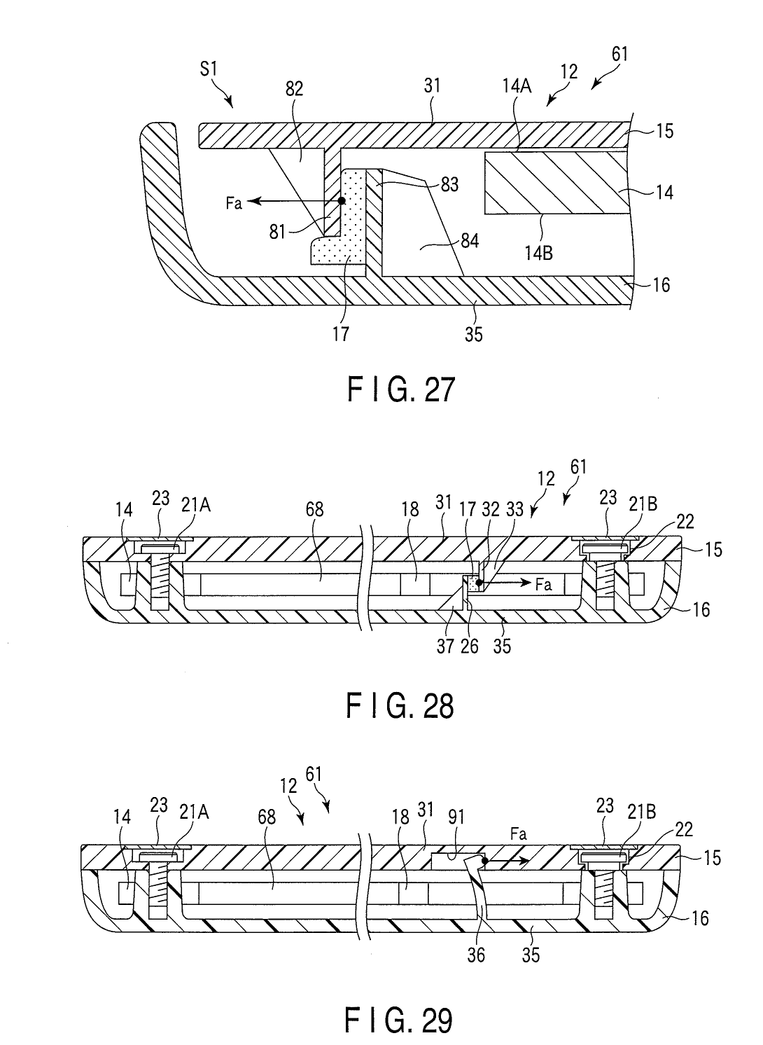

The first member 15 may thermally expand due to an influence of the light source 18 as a heating member. In this case, the elastic body 17 functions as follows. In a first state S1 in which the first member 15 has not thermally expanded as shown in FIG. 27, the elastic body 17 exerts force Fa on the first member 15 outward. In a second state S2 in which the first member 15 has thermally expanded, the elastic body 17 exerts force Fb on the first member 15 outward.

In the twelfth embodiment, the first projections 81, the second projections 36 and the elastic bodies 17 are arranged along the height direction H. With this arrangement also, as well as the embodiments described above, the first main body 31 is prevented from bending and the first member 15 will be effectively prevented from rising above the display panel 14.

Next, a modification of the sixth embodiment will be described with reference to FIG. 28. In the following, parts different from those of the sixth embodiment will be explained.

As shown in FIG. 28, in this modification, the first member 15 comprises a first projection (contact portion) 32 and the second member 16 comprises a second projection 36. The portable computer 61 comprises an elastic body 17 between the first projection 32 and the second projection 36. It also comprises a display panel (display device) 14 and a light source (heating element) 18 as a back light of the display panel 14 between the first member 15 and the second member 16, which constitute a casing.

The portable computer 61 comprises first and second fixing members 21A and 21B which fix the first member 15 and the second member 16 at the end portions in the width direction of the portable computer 61. The first fixing member 21A fixes the first member 15 and the second member 16 to prevent displacement between the first member 15 and the second member 16. The second fixing member 21B is fitted in a through hole 22 with a play (clearance) therebetween. Thus, the first member 15 is movable outward around the through hole 22.

In this modification, the second projection 36 and the elastic body 17 constitute a pressing member. The pressing member is brought into contact with the first projection 32 in the area between the first member 15 and the second member 16, and forces the first projection 32 in a direction away from the light source (heating element) 18 with force Fa. Although not shown in the drawings, even after the first member 15 has been thermally expanded by the influence of the light source (heating body) 18, the elastic body 17 can force the first member 15 outward with force Fb. Thus, this modification also prevents the first member 15 from separating above the display panel 14.

Next, a first modification of the eleventh embodiment will be described with reference to FIG. 29. In the following, parts different from those of the eleventh embodiment will be explained.

As shown in FIG. 29, in this modification, the first member 15 comprises a recess 91 as an example of the contact portion. The second member 16 comprises a second projection 36, which is elastic. The eleventh embodiment comprises a display panel (display device) 14 and a light source (heating element) 18 as a back light of the display panel 14 between the first member 15 and the second member 16, which constitute a casing.

The portable computer 61 comprises first and second fixing members 21A and 21B which fix the first member 15 and the second member 16 at the end portions in the width direction of the portable computer 61. The first fixing member 21A fixes the first member 15 and the second member 16 to prevent displacement between the first member 15 and the second member 16. The second fixing 21B is fitted in a through hole 22 with a play (clearance) therebetween. Thus, the first member 15 is movable outward around the through hole 22.

In this modification, the second projection 36 constitutes a pressing member. The second projection 36 is brought into contact with the recess 91 in the area between the first member 15 and the second member 16, and forces the recess 91 in a direction away from the light source (heating element) 18 with force Fa. Although not shown in the drawings, even after the first member 15 has been thermally expanded by the influence of the light source (heating body) 18, the second projection 36 can force the first member 15 outward with force Fb. Thus, this modification also prevents the first member 15 from separating above the display panel 14.

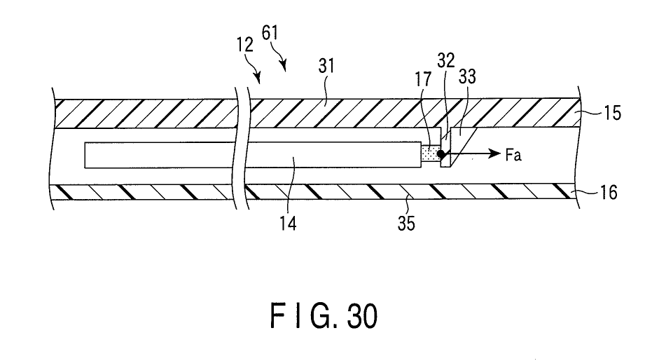

Next, a second modification of the eleventh embodiment will be described with reference to FIG. 30. In the following, parts different from those of the eleventh embodiment will be explained.

As shown in FIG. 30, in this modification, the first member 15 comprises a first projection (contact portion) 32. The second member 16 does not comprise a second projection 36. The portable computer 61 comprises an elastic body 17 between the first projection 32 and an end of the display panel (display device) 14. In this modification, the display panel (display device) 14 is an example of the heating element.

The portable computer 61 comprises first and second fixing members 21A and 21B which fix the first member 15 and the second member 16 at the end portions in the width direction of the portable computer 61. The first fixing member 21A fixes the first member 15 and the second member 16 to prevent displacement between the first member 15 and the second member 16. The second fixing member 21B is fitted in a through hole 22 with a play (clearance) therebetween. Thus, the first member 15 is movable outward around the through hole 22.

In this modification, the elastic body 17 constitutes a pressing member. The elastic body 17 is brought into contact with the first projection 32 in the area between the first member 15 and the second member 16, and forces the first projection 32 in a direction away from the display panel (heating element) 14 with force Fa. Although not shown in the drawings, even after the first member 15 has been thermally expanded by the influence of the display panel (heating body) 14, the elastic body 17 can force the first member 15 outward with force Fb. Thus, this modification also prevents the first member 15 from separating above the display panel 14.

The modifications shown in FIG. 28 to FIG. 30 are also applicable to the television 11 of the first to fifth embodiments.

The electronic apparatus is not limited to the television 11 or the portable computer 61 in the embodiments described above, but may be another type of electronic apparatus, such as a cellular phone or an electronic book reader which electronically displays a book or image.

Further, the electronic apparatus is not limited to the above embodiments without change, but may be embodied in practice within the spirit of the invention while the structural elements are modified. Furthermore, various inventions can be achieved by suitably combining a plurality of structural elements in the embodiments described above. For example, some of the structural elements disclosed as the embodiments may be deleted. Moreover, structural elements of different embodiments may be suitably combined.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a display panel comprising a first face and a second face;
a first member comprising a first main body surrounding the first face of the display panel, and a pair of first projections projecting from the first main body, the first main body being thermally expandable;
a second member comprising a second main body surrounding the second face of the display panel, and a pair of second projections projecting from the second main body, the pair of second projections located on inner sides of the first projections;
a heating element between the first member and the second member; and
a pair of elastic bodies between the pair of first projections and the pair of second projections,
wherein the pair of elastic bodies are configured to exert a first outward force on the pair of first projections, the first outward force sufficient to increase a distance between the pair of first projections, when the first main body is not thermally expanded.

2. The electronic apparatus of claim 1, wherein the pair of elastic bodies are configured to exert a second outward force the pair of first projections, the second outward force sufficient to increase the distance between the first projections, when the first main body is thermally expanded.

3. The electronic apparatus of claim 2, wherein the heating element is between the pair of first projections.

4. The electronic apparatus of claim 3, further comprising:
a plurality of through holes, in the first main body, near the pair of first projections; and
fixing members movably fitted in the through holes, the fixing members configured to fix the first member and the second member.

5. The electronic apparatus of claim 4, wherein:
each elastic member of the pair of elastic bodies are respectively fixed to a second projection of the pair of second projections; and
each the first projections of the pair of first projections comprise top ends and base ends, the top ends of the pair of first projections being farther apart from each other than the base ends of the pair of first projections.

6. The electronic apparatus of claim 5, wherein each elastic body of the pair of the elastic bodies comprise facing portions which face respective first projections, the facing portions being slanted inward.

7. The electronic apparatus of claim 4, wherein the first projections each comprise engagement portions configured to engage with the second member.

8. The electronic apparatus of claim 4, wherein:
the second member comprises a plurality of retainers configured to retain the display panel; and
the second projections are each integrated with the retainers.

9. An electronic apparatus comprising:
a casing comprising a first member and a second member, of the members comprising resin;
a display device in the casing;
a heating element in the casing;
a contact portion in the first member; and
a forcing member between the heating element and the contact portion in the casing, in contact with the contact portion, and configured to exert a force on the contact portion in a direction away from the heating body.
